(19) United States
(12) Patent Application Publication
(10) Pub. No.: US 2024/0030024 A1
(43) Pub. Date: Jan. 25, 2024

(54) LAYER DEPOSITION METHOD AND LAYER DEPOSITION APPARATUS

(71) Applicant: Samsung Electronics Co., Ltd., Suwon-si (KR)

(72) Inventors: Intak Jeon, Suwon-si (KR); Hanjin Lim, Suwon-si (KR); Hyungsuk Jung, Suwon-si (KR)

(21) Appl. No.: 18/137,339

(22) Filed: Apr. 20, 2023

(30) Foreign Application Priority Data
Jul. 19, 2022 (KR) 10-2022-0088812

(51) Int. Cl. H01L 21/02; H01L 21/3105

(52) U.S. Cl. CPC H01L 21/0228; H01L 21/02181; H01L 21/02189; H01L 21/02205; H01L 21/31055

(57) ABSTRACT

In a method of a method of depositing a layer, a substrate is loaded on a substrate stage within a chamber. A precursor gas and a reaction gas are alternately supplied into the chamber to form at least one atomic layer. A surface of the at least one atomic layer is planarized by applying pressure on the surface of the at least one atomic layer to diffuse atoms located on the surface having a relatively high curvature. The precursor gas and the reaction gas are alternately supplied into the chamber to form at least one atomic layer on the planarized atomic layer.

### PRIORITY STATEMENT

This application claims priority under 35 U.S.C. § 119 to Korean Patent Application No. 10-2022-0088812, filed on Jul. 19, 2022 in the Korean Intellectual Property Office (KIPO), the contents of which are herein incorporated by reference in their entirety.

### BACKGROUND

### 1. Field

Example embodiments relate to a layer deposition method and a layer deposition apparatus. More particularly, example embodiments relate to a method of depositing a layer such as a dielectric layer by an atomic layer deposition process and a layer deposition apparatus for performed the same.

### 2. Description of the Related Art

In a structure having a high aspect ratio, such as a capacitor of a DRAM device, a thin layer such as a dielectric layer may be formed by an atomic layer deposition (ALD) process. When one thin atomic layer is deposited, the atomic layer does not grow flat and has a rough surface, which may increase the surface roughness. Accordingly, as the atomic layers having high surface roughness are stacked to form the dielectric layer of the capacitor, it is difficult for the capacitor to have high capacitance and low leakage current.

### SUMMARY

Example embodiments provide a layer deposition method capable of forming a thin film having excellent properties by stacking atomic layers having a reduced surface roughness.

Example embodiments provide a layer deposition apparatus for performing the above layer deposition method

According to example embodiments, in a method of depositing a layer, a substrate is loaded on a substrate stage within a chamber. A precursor gas and a reaction gas are alternately supplied into the chamber to form at least one atomic layer. A surface of the at least one atomic layer is planarized by applying pressure on the surface of the at least one atomic layer to diffuse atoms located on the surface having a relatively high curvature. The precursor gas and the reaction gas are alternately supplied into the chamber to form at least one atomic layer on the planarized atomic layer.

According to example embodiments, in a method of depositing a layer, a precursor gas and a reaction gas are alternately supplied into a chamber to form at least one atomic layer (step i)). Atoms located on a surface of the at least one atomic layer are diffused to planarize a surface of the at least one atomic layer (step ii)). The step i) and the step ii) are repeatedly performed until the atomic layer has a desired thickness.

According to example embodiments, a layer deposition apparatus includes a chamber, a substrate stage configured to support a substrate within the chamber, a gas supply configured to alternately supply a precursor gas and a reaction gas into to chamber to form at least one atomic layer on the substrate, and an atomic diffuser configured to apply a pressure on a surface of the at least one atomic layer to diffuse atoms located on the surface of the at least one atomic layer to thereby planarize the surface of the at least one atomic layer.

According to example embodiments, a precursor gas and a reaction gas may be alternately supplied into a chamber to form at least one atomic layer on a substrate, and atoms located on a surface of the at least one atomic layer may be diffused to planarize the surface of the atomic layer, and the atomic layer deposition step and the surface planarization step may be alternately and repeatedly performed until the atomic layer has a desired thickness.

When the precursor gas and the reaction gas react to form one atomic layer on the substrate, the atomic layer may not grow flat and may have an uneven surface. The atoms on a convex surface of the atomic layer may have higher chemical potential than the atoms on a surface with relatively low curvature. By applying a pressure equal to or greater than the chemical potential (threshold) on the atoms on the convex surface, the atoms located on the surface of the at least one atomic layer may be diffused to reduce the surface roughness of the surface of the atomic layer.

Thus, as the atomic layers having low surface roughness are stacked to form a dielectric layer of a capacitor, the capacitor may have desired characteristics such as high capacitance and low leakage current.

### BRIEF DESCRIPTION OF THE DRAWINGS

Example embodiments will be more clearly understood from the following detailed description taken in conjunction with the accompanying drawings. FIGS. 1 to 15 represent non-limiting, example embodiments as described herein.

FIG. 1 is a block diagram illustrating a layer deposition apparatus in accordance with example embodiments.

FIG. 2 is a flow chart illustrating a method for depositing a thin layer in accordance with example embodiments.

FIG. 3 is a timing diagram illustrating the layer deposition method of FIG. 2.

FIGS. 4A, 5A and 6A are cross-sectional views illustrating an atomic layer formed on a substrate by the layer deposition method of FIG. 2.

FIGS. 4B, 5B and 6B are enlarged cross-sectional views illustrating portion ‘A’ of FIGS. 4A, 5A and 6A.

FIG. 7 is a timing diagram illustrating a layer deposition method in accordance with example embodiments.

FIG. 8 is a timing diagram illustrating a layer deposition method in accordance with example embodiments.

FIGS. 9 to 15 are cross-sectional views illustrating a method of manufacturing a capacitor in accordance with example embodiments.

### DETAILED DESCRIPTION OF EXAMPLE EMBODIMENTS

Hereinafter, example embodiments will be explained in detail with reference to the accompanying drawings.

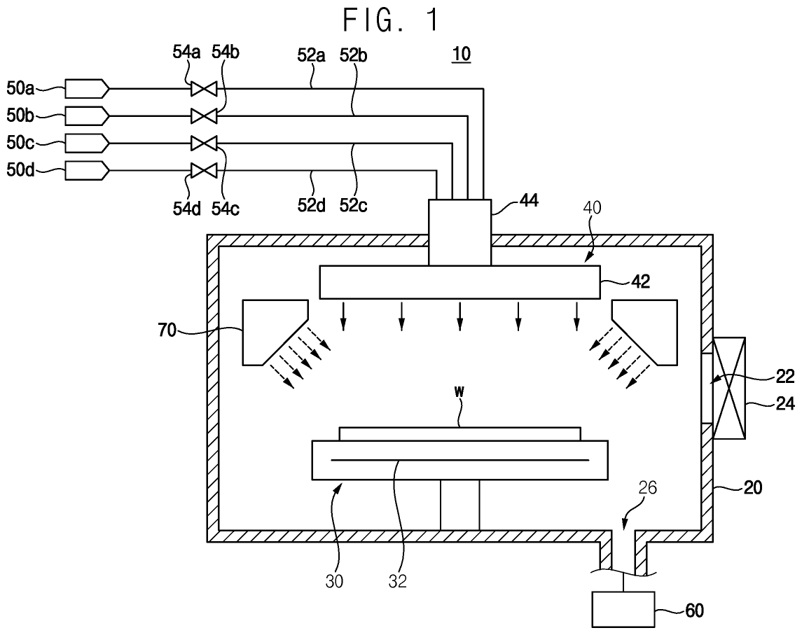

FIG. 1 is a block diagram illustrating a layer deposition apparatus in accordance with example embodiments.

Referring to FIG. 1, a layer deposition apparatus 10 may include a chamber 20, a substrate stage 30, a gas supply 40 and an atomic diffuser 70. In addition, the layer deposition apparatus 10 may further include an exhaust portion 60, a temperature control mechanism, etc.

In example embodiments, the layer deposition apparatus 10 may be a deposition apparatus configured to form a thin layer on a substrate such as a semiconductor wafer W. For example, the layer deposition apparatus 10 may be an atomic layer deposition (ALD) apparatus configured to alternately supply a precursor gas and a reactive gas reacting with each other on the substrate to form a metal oxide such as zirconium oxide (ZrO₂), hafnium oxide (HfO₂), etc. by. However, it may not be limited thereto, and the layer deposition apparatus 10 may be, for example, a chemical vapor deposition (CVD) apparatus.

The substrate W may be an object on which a dielectric layer is formed. The substrate W may be manufactured from, for example, a semiconductor wafer such as a silicon wafer or a germanium wafer. Meanwhile, various structures may be further formed on the substrate W.

For example, a conductive layer or an electrode including metal, metal nitride, metal silicide, metal oxide, etc., or an insulating layer including silicon oxide, silicon nitride, etc. may be further formed on the substrate W. In some embodiments, the thin layer may be deposited on a structure having a pillar or cylinder shape having a high aspect ratio or a hole or an opening therein through processes described below.

The chamber 20 may include a cylindrical processing container. The chamber 20 may include aluminum, stainless steel, or the like. A gate 22 for loading/unloading the wafer W may be formed in a sidewall of the chamber 20, and a gate valve 24 for opening and closing the gate 22 may be installed. In addition, a heater (not illustrated) may be installed on the sidewall of the chamber 20 as a portion of the temperature control mechanism to control the temperature of the chamber 20 during layer deposition. For example, the temperature inside the chamber 20 may be maintained in a range of about 200° C. to about 600° C.

An exhaust port 26 may be installed in a bottom wall of the chamber 20. The exhaust port 26 may be connected to the exhaust portion 60 having a vacuum pump, a pressure control valve, or the like, through an exhaust pipe. The exhaust portion 60 may maintain pressure inside the chamber 20 so that a processing space inside the chamber 20 may be depressurized to a desired vacuum level. In addition, process by-products and residual process gases in the chamber 20 may be discharged through the exhaust port 26. Alternatively, the exhaust port 26 may be installed in the side wall of the chamber 20.

The substrate stage 30 may be disposed inside the chamber 20 and may serve as a susceptor on which the substrate W is loaded. One or a plurality of substrates W may be disposed on the substrate stage 30. The substrate stage 30 may be installed to be movable up and down. Additionally, the substrate stage 30 may be installed to be rotatable at a predetermined speed.

The substrate stage 30 may include a heater 32 therein. The heater 32 may be connected to a heater power supply (not illustrated) and may heat the substrate W to a desired temperature. The heater 32 may be heated to a temperature range of about 200° C. to 700° C. The heater 32 may include coils that are arranged concentrically. In addition, the substrate stage 30 may further include an electrostatic electrode (not illustrated) configured to hold the wafer W thereon using electrostatic force.

In example embodiments, the gas supply 40 may alternately supply the precursor gas and the reaction gas to form at least one atomic layer on the substrate W.

In particular, the gas supply 40 may include a shower head 42 as a gas injection nozzle. The shower head 42 may be installed over the substrate stage 30 to face the substrate stage 30. The shower head 42 may be installed in the middle region of an upper sidewall of the chamber 20 to be connected to an introduction portion 44. The shower head 42 may supply a thin layer source gas including a precursor gas, a reaction gas, a purge gas, a boost gas, etc. into the chamber 20 through injection holes toward the substrate stage 30.

The layer deposition apparatus 10 may include a plurality of gas supply sources 50a, 50b, 50c and 50d configured to supply the gases and gas supply lines 52a, 52b, 52c and 52d connected to each of the gas supply sources to supply the gases to the chamber 20.

A first gas supply source 50a may supply the precursor gas. For example, the precursor gas may include zirconium (Zr), hafnium (Hf), titanium (Ti), tantalum (Ta), etc. A second gas supply source 50b may supply the reaction gas. The reaction gas may include oxygen (O₂), ozone (O₃), etc. The third gas supply source 50c may supply the purge gas. The purge gas may include nitrogen (N₂). A fourth gas supply source 50d may supply the boost gas. The boost gas may be used to increase the pressure inside the chamber 20 and may include an inert gas such as argon (Ar), helium (He), nitrogen (N₂), etc.

The precursor gas from the first gas supply source 50a may be introduced into the shower head 42 through the first gas supply line 52a. The reaction gas from the second gas supply source 50b may be introduced into the shower head 42 through the second gas supply line 52b. The purge gas from the third gas supply source 50c may be introduced into the shower head 42 through the third gas supply line 52c. The boost gas from the fourth gas supply source 50d may be introduced into the shower head 42 through the fourth gas supply line 52d.

Although it is not illustrated in the figures, the gas supply 40 may additionally supply an additive gas to the chamber 20 in order to facilitate the atomic layer deposition reaction. For example, the shower head 42 may spray the additive gas. Alternatively, the gas supply 40 may further include a gas injection nozzle installed on the side wall of the chamber 20 to inject the additive gas.

Valves 54a, 54b, 54c and 54d may be supply control elements for supplying and blocking the gas. In the atomic layer deposition process (ALD), it may be desirable to use a precisely controllable valve because gas supply and cut off are required for a relatively short period of time. As described above, the gases may be supplied into the chamber 20 using a shower type, but it may not be limited thereto. For example, the gases may be supplied into the chamber 20 using a flow type gas supply element. A combination of the two types of gas supply elements may be used if necessary.

In the atomic layer deposition process, the temperature of the chamber 20 may be maintained at about 550° C. The precursor gas from the first gas supply source 50a may be introduced into the shower head 42 through the first gas supply line 52a, and the shower head 42 may spray the precursor gas onto the wafer W on the substrate stage 30. When the supply of the precursor gas into the chamber 20 is completed, the purge gas may be supplied into the chamber 20 for a predetermined time to purge the inside of the chamber 20, and after the purging of the interior of the chamber 20 is completed, the reaction gas may be supplied into the chamber 20. The reaction gas from the second gas supply source 50b may be introduced into the shower head 42 through a second gas supply line 52b, and the shower head 42 may spray the reaction gas onto the wafer W on the substrate stage 30. Accordingly, an atomic layer such as a zirconium oxide layer (ZrO₂), a hafnium oxide layer (HfO₂), etc. may be formed on the substrate W. After the atomic layer is formed, the purge gas may be supplied into the chamber 20 to purge the inside of the chamber 20.

In example embodiments, the atomic diffuser 70 may apply pressure to a surface of the atomic layer formed on the substrate W to diffuse atoms located on the surface of the atomic layer to planarize the surface of the atomic layer. When the atomic layer is formed on the substrate W, the atomic layer may not grow flat and have an uneven surface, and thus surface roughness may increase. The atomic diffuser 70 may planarize the surface of the atomic layer to reduce the surface roughness.

One atomic diffuser 70 may be installed in the chamber 20 to apply pressure to the surface of the atomic layer formed on the substrate W. Alternatively, a plurality of the atomic diffusers 70 may be installed in the chamber 20.

For example, the atomic diffuser 70 may include at least one of a surface resonator, an electromagnetic wave generator and an ion implanter. The surface resonator may apply vibration pressure to the surface of the atomic layer. The electromagnetic wave generator may apply radiation pressure to the surface of the atomic layer. The ion implanter may generate a mechanical bombardment on the surface of the atomic layer. For example, the electromagnetic wave generator may include a laser generator, a sound wave generator, and the like according to a wavelength range of the light source. The laser generator may include a laser annealing device. The ion implanter may include an atom gun or the like.

The gas supply 40 may alternately supply the precursor gas and the reaction gas into the chamber 20 to form at least one atomic layer on the substrate W, and the atomic diffuser 70 may diffuse atoms located on the surface of the at least one atom layer to reduce the surface roughness of the surface of the atomic layer. The gas supply 40 and the atomic diffuser 70 may repeatedly perform the atomic layer deposition and the surface planarization until the atomic layer has a desired thickness.

Accordingly, as the atomic layers having low surface roughness are stacked to form a dielectric layer of a capacitor, the capacitor may have desired characteristics such as high capacitance and low leakage current.

Hereinafter, a method of depositing a thin layer using the layer deposition apparatus of FIG. 1 will be described.

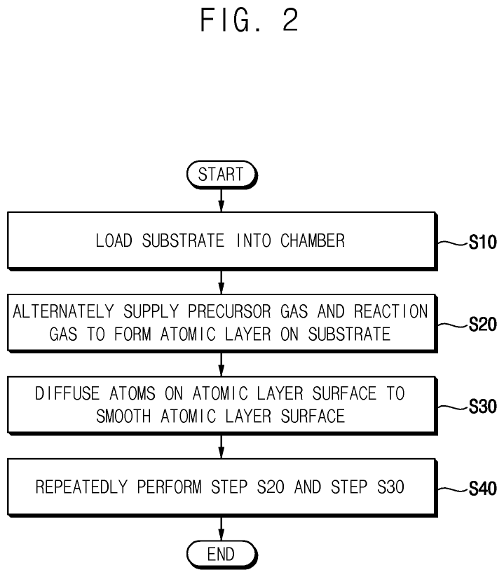

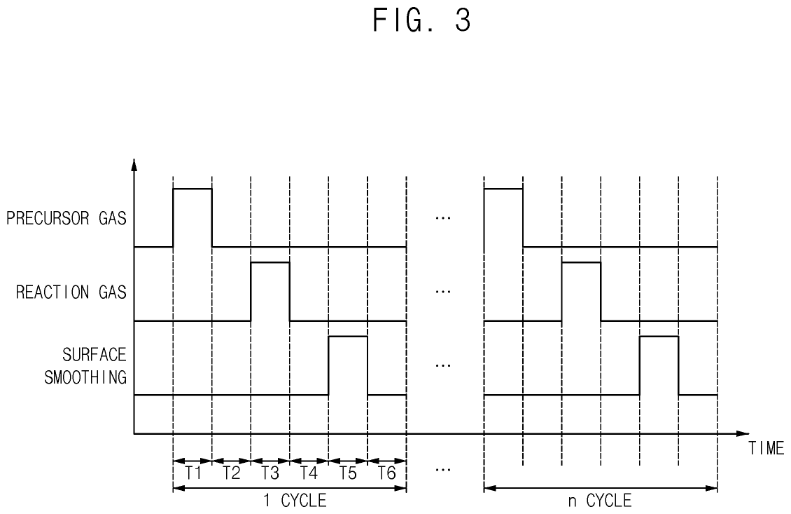

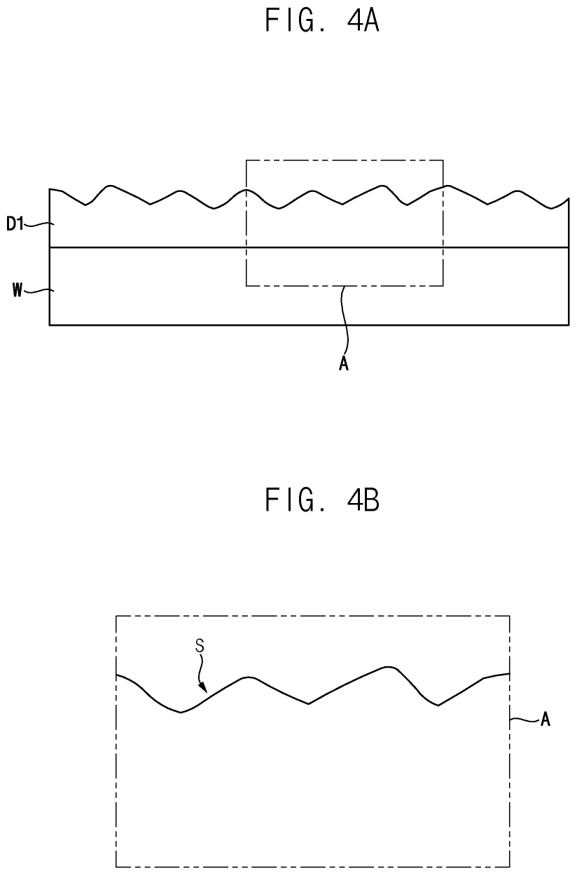

FIG. 2 is a flow chart illustrating a method for depositing a thin layer in accordance with example embodiments. FIG. 3 is a timing diagram illustrating the layer deposition method of FIG. 2. FIGS. 4A, 5A and 6A are cross-sectional views illustrating an atomic layer formed on a substrate by the layer deposition method of FIG. 2. FIGS. 4B, 5B and 6B are enlarged cross-sectional views illustrating portion ‘A’ of FIGS. 4A, 5A and 6A.

Referring To FIGS. 1 to 6B, first, a substrate W may be loaded into the chamber 20 (S10).

In example embodiments, the chamber 20 may be a chamber for an ALD process. The substrate W may be an object on which a thin layer is formed. The substrate W may be manufactured from, for example, a semiconductor wafer such as a silicon wafer or a germanium wafer. Various structures (not illustrated) may be further formed on the substrate W.

Then, a precursor gas and a reaction gas may be alternately supplied form an atomic layer D1 on the substrate W (S20), and atoms located on a surface of the atomic layer may be diffused to planarize the surface of the atomic layer D1 (S30), and the step S20 and the step S30 may be alternately and repeatedly performed to form an atomic layer having a desired thickness (S40).

In example embodiments, before supplying the precursor gas and the reaction gas into the chamber 20, the inside of the chamber 20 may be depressurized to a vacuum atmosphere. For example, the step of forming the atomic layer D1 may be performed at a chamber pressure of 5 torr. In addition, the temperature of the chamber 20 may be within a range of 360° C. to 500° C., but may not be limited thereto.

The precursor gas and the reaction gas as the thin layer source gas may be supplied onto the substrate W on the substrate stage 30 in the chamber 20 through the shower head 42.

As illustrated in FIG. 3, the atomic layer formation process of one cycle may include a precursor gas supply step (T1), a purge step (T2), a reactive gas supply step (T3), a purge step (T4), a surface planarization step (T5), and a purge step (T6).

In particular, after the substrate W is loaded into the chamber 20, the precursor gas containing zirconium (Zr) may be supplied into the chamber 20 for T1 time to adsorb zirconium (Zr) on the surface of the substrate W. Then, purging may be performed for T2 time to remove unreacted gas and reaction by-products. In this case, an inert gas such as argon or nitrogen may be used as the purge gas.

Then, the reaction gas containing oxygen (O₂) or ozone (O₃) may be supplied into the chamber 20 for T3 time to react with zirconium (Zr) adsorbed on the surface of the substrate (W) to form an atomic layer D1 including zirconium oxide (ZrO₂). Then, purging may be performed for T4 time to remove unreacted gas and reaction by-products. The atomic layer D1 may be formed to have a thickness of 0.2 Å to 0.8 Å.

Then, a surface of the atomic layer D1 may be planarized by applying pressure to the surface of the atomic layer D1 for T5 time to diffuse atoms located on the surface having a relatively high curvature. Then, purging may be performed for T6 time to remove unreacted gas and reaction by-products.

The atomic layer forming process of one cycle may be repeated a plurality of times to form an atomic layer having a desired thickness. The desired thickness of the atomic layer may be within a range of 30 Å to 80 Å.

As illustrated in FIGS. 4A and 4B, in the atomic layer formation process of one cycle, when the precursor gas and the reaction gas react to form one atomic layer D1 on the substrate W, the atomic layer D1 may not grow flat and may have an uneven surface S.

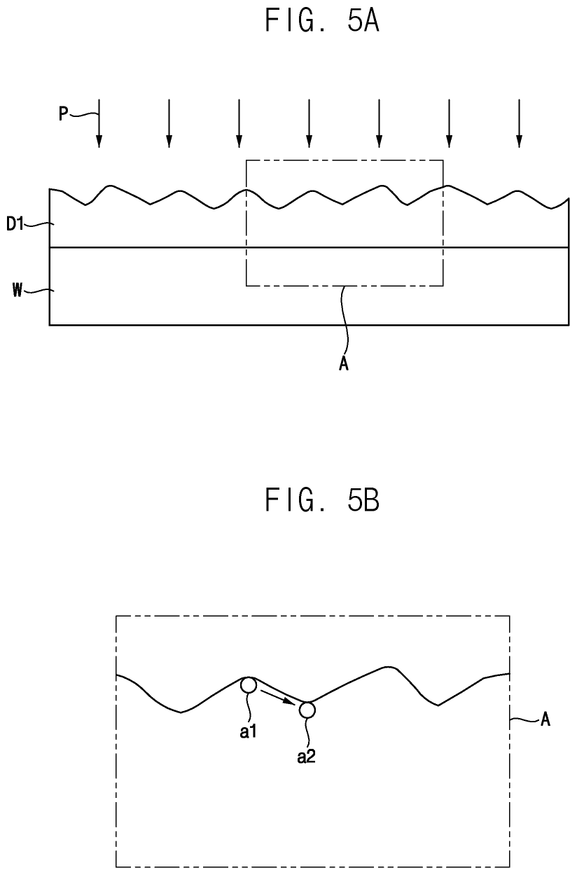

As illustrated in FIGS. 5A and 5B, the surface of the atomic layer D1 may be planarized by applying pressure P to the surface of the atomic layer D1. Chemical potential μ of an atom on a spherical surface with respect to a flat reference surface may be expressed by Equation (1) below.

$$μ = Ω \frac{2 γ}{R} \qquad Equation ( 1 )$$

Here, μ is the chemical potential of the atom on the surface, Ω is the atomic volume, γ is the surface energy (tension), and R is the radius of the spherical particle.

The chemical potential of atoms in the atomic layer D1 may be affected by the radius of curvature of the surface. As can be seen from FIG. 5B that the chemical potential of the atom (a1) on the convex surface of the atomic layer with relatively large curvature is greater than that of the atom (a2) on the surface with relatively small curvature.

Thermodynamically, atoms on a convex surface can have higher chemical potential. The atomic diffuser 70 may apply a pressure equal to or greater than the chemical potential (threshold value) on the atom a1 having higher chemical potential on the convex surface to diffuse the atom to a low energy state and low curvature surface.

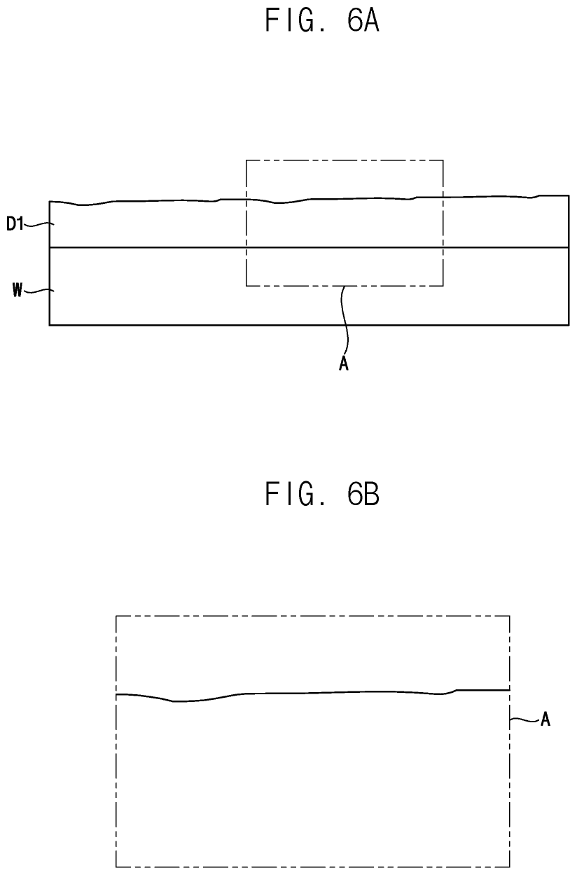

As illustrated in FIGS. 6A and 6B, the surface roughness of the surface of the atomic layer D1 may be reduced by the surface planarization step.

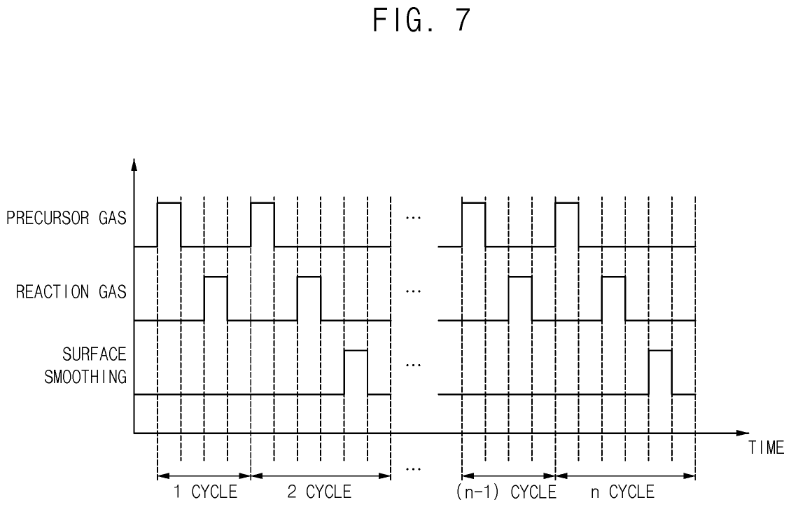

FIG. 7 is a timing diagram illustrating a layer deposition method in accordance with example embodiments. The layer deposition method may be substantially the same as or similar to the layer deposition method described with reference to FIG. 3 except for the sequence of performing a surface planarization step. Thus, same reference numerals will be used to refer to the same or like elements and any further repetitive explanation concerning the above elements will be omitted.

Referring to FIG. 7, a surface planarization step for reducing a surface roughness of a surface of an atomic layer may be performed only in some cycles. The surface planarization step may be performed after a plurality of atomic layers is successively formed.

In example embodiments, the surface planarization step may be performed after two atomic layers are successively formed. The surface planarization step may not be performed during an atomic layer formation process of an odd-numbered cycle, but may be performed during an atomic layer formation process of an even-numbered cycle. Alternatively, the surface planarization step may be performed in the atomic layer formation process of the odd-numbered cycle and not be performed during the atomic layer formation process of the even-numbered cycle. However, it may not be limited thereto, and it will be understood that, for example, the surface planarization step may be performed after three or four atomic layers are successively formed.

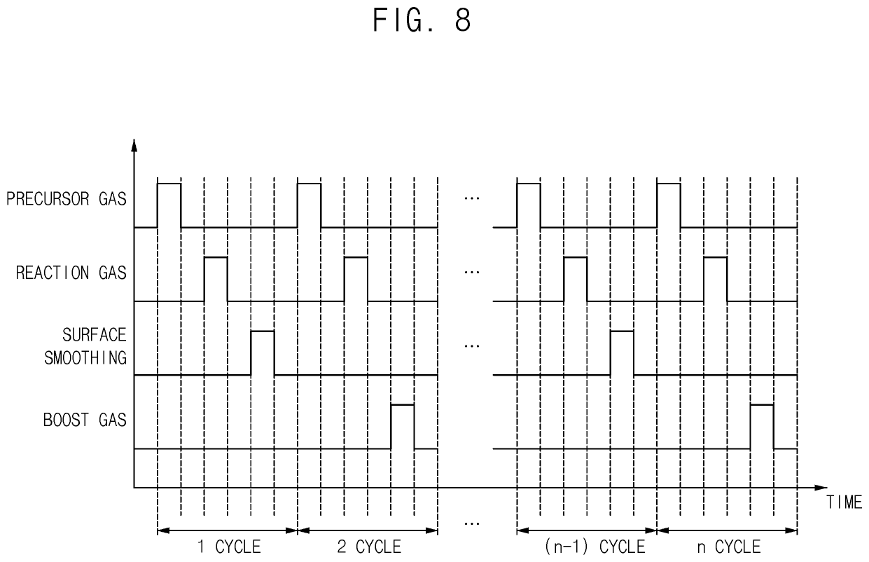

FIG. 8 is a timing diagram illustrating a layer deposition method in accordance with example embodiments. The layer deposition method may be substantially the same as or similar to the layer deposition method described with reference to FIG. 7 except for an additional step of supplying a boost gas. Thus, same reference numerals will be used to refer to the same or like elements and any further repetitive explanation concerning the above elements will be omitted.

Referring to FIG. 8, a layer deposition method may further include a step of increasing pressure inside the chamber 20 to improve properties of a thin layer formed on the substrate.

In example embodiments, a boost gas may be supplied into the chamber 20 in a specific cycle to increase the pressure inside the chamber 20 such that the pressure is applied to a surface of the formed layer.

The step of supplying the boost gas may be performed after two atomic layers are successively formed. The step of supplying the boost gas may not be performed during an atomic layer formation process of an odd-numbered cycle, but may be performed during an atomic layer formation process of an even-numbered cycle. Alternatively, the step of supplying the boost gas may be performed in the atomic layer formation process of the odd-numbered cycle and not be performed during the atomic layer formation process of the even-numbered cycle. However, it may not be limited thereto, and it will be understood that, for example, the step of supplying the boost gas may be performed after three or four atomic layers are formed.

Alternatively, the step of supplying the boost gas may be performed after the step of supplying of the precursor gas or after the step of supplying of the reaction gas. The step of supplying the boost gas may be performed simultaneously with the step of supplying the precursor gas or simultaneously with the step of supplying the reaction gas. The step of supplying the boost gas may be performed after or simultaneously with the surface planarization step. The pressure of the chamber 20 may be increased to 1 atm or more by the step of supplying the boost gas.

Hereinafter, a method of manufacturing a capacitor having a lower electrode with a pillar shape using the layer deposition apparatus of FIG. 1 and the layer deposition method of FIG. 3 will be described.

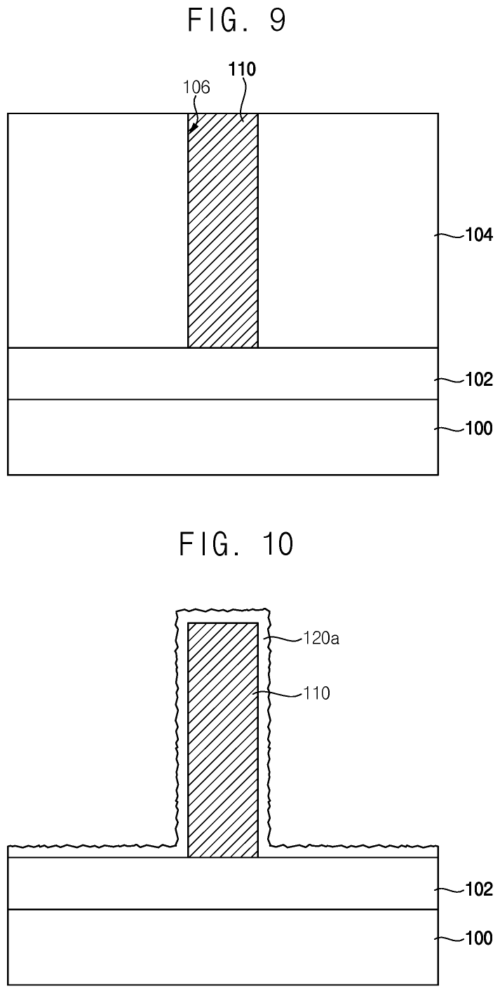

FIGS. 9 to 15 are cross-sectional views illustrating a method of manufacturing a capacitor in accordance with example embodiments.

Referring to FIG. 9, a mold layer 104 including a hole 106 may be formed on a substrate 100. The hole 106 may be formed in a region on which the lower electrode is to be formed.

Before forming the mold layer 104, a lower structure 102 including lower circuits including a transistor, a contact plug and a conductive line and an insulation interlayer covering the lower circuits may be further formed on the substrate 100.

A lower electrode layer may be formed on the mold layer 104 to fill up the hole 106. The lower electrode layer may be planarized until an upper surface of the mold layer 104 is exposed, to form a lower electrode 110 in the hole 106.

In example embodiments, the lower electrode layer may be formed by a deposition process such as physical vapor deposition (PVD), chemical vapor deposition (CVD) and atomic layer deposition (ALD). In addition, the planarization process may include a chemical mechanical polishing process and/or an etch-back process.

In some example embodiments, the lower electrode layer may be formed on the lower structure 102 and the lower electrode layer may be patterned by a photolithography process to form the lower electrode 110. In this case, the step of forming the mold layer may be omitted.

Referring to FIGS. 10 to 14, a dielectric layer 120 may be formed to a have a uniform thickness on a sidewall and an upper surface of the lower electrode 110 and the lower structure 102.

As illustrated in FIG. 10, the mold layer 104 may be removed to expose the sidewall and the upper surface of the pillar-shaped lower electrode 110. Then, a first dielectric layer 120a may be formed on the sidewall and the upper surface of the lower electrode 110 and the lower structure 102. The first dielectric layer 120a may include a metal oxide having a low dielectric constant, for example, at least one selected from HfO₂, ZrO₂, TiO₂, TaO₂ and La₂O₃.

In example embodiments, after the substrate 100 on which the lower electrode 110 is formed is loaded into the chamber 20 of FIG. 1, the first dielectric layer 120a may be formed by an atomic layer formation process of one cycle. The atomic layer forming process of one cycle may include a precursor gas supply step T1, a purge step T2, a reactive gas supply step T3, a purge step T4, a surface planarization step T5 and a purge step T6. The first dielectric layer 120a may be formed to have a thickness of 0.2 Å to 0.8 Å by the atomic layer formation process of one cycle.

During one cycle of atomic layer formation, when the precursor gas and the reaction gas react each other to form one first dielectric layer 120a on the substrate 100, the first dielectric layer 120a may not grow flat and may have a rough surface.

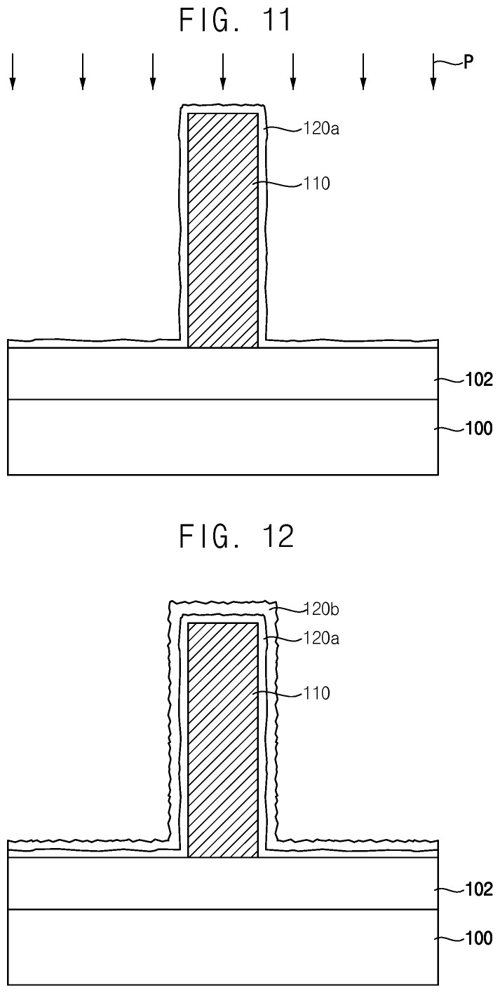

As illustrated in FIG. 11, a surface of the first dielectric layer 120a may be planarized by applying a pressure P to the surface of the first dielectric layer 120a. An atomic diffuser 70 may apply a pressure that is equal to or greater than the chemical potential on atoms having high chemical potential on the convex surface of the first dielectric layer 120a to diffuse the atoms to a low curvature surface with a lower energy. Accordingly, the surface roughness of the surface of the first dielectric layer 120a may be reduced by the surface planarization step.

As illustrated in FIG. 12, a second dielectric layer 120b may be formed on the first dielectric layer 120a by performing steps similar to the steps described with reference to FIG. 10.

During one cycle of atomic layer formation, when the precursor gas and the reaction gas react to form the second dielectric layer 120b on the first dielectric layer 120a, the second dielectric layer 120b may not grow flat and may have a rough surface.

As illustrated in FIG. 13, the second dielectric layer 120b may be planarized by applying a pressure P to a surface of the second dielectric layer 120b by performing a step similar to the step described with reference to FIG. 11. The atomic diffuser 70 may diffuse atoms located on the surface of the second dielectric layer 120b to reduce the surface roughness of the surface of the second dielectric layer 120b.

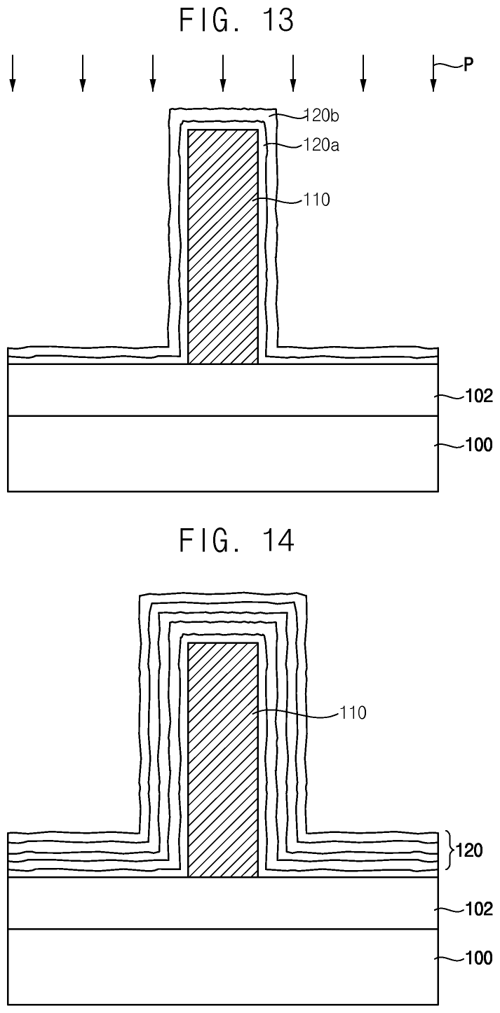

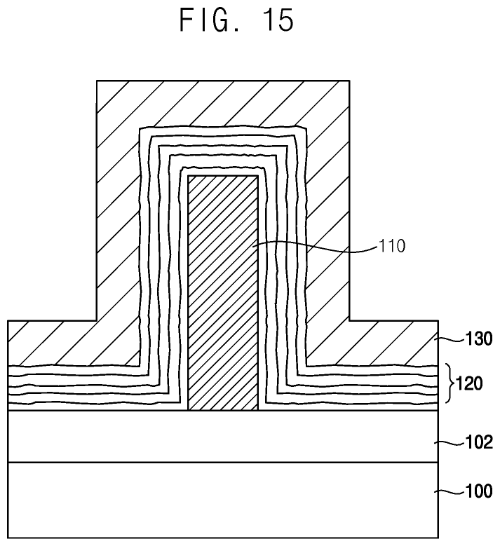

As illustrated in FIG. 14, the atomic layer forming process of one cycle may be performed repeatedly a plurality of times to form the dielectric layer 120 having a desired thickness. The desired thickness of the dielectric layer may be within a range of 30 Å to 80 Å.

Referring to FIG. 15, an upper electrode 130 may be formed on the dielectric layer 120.

In example embodiments, the upper electrode 130 may be formed of the same material as the lower electrode 110 or a material different from that of the lower electrode 110.

For example, the upper electrode 130 may be deposited by a deposition process such as physical vapor deposition (PVD), chemical vapor deposition (CVD), and atomic layer deposition (ALD).

In example embodiments, after forming the upper electrode 130, a heat treatment process may be performed. The layers included in the dielectric layer 120 may be additionally crystallized through the heat treatment process.

Accordingly, as the atomic layers having low surface roughness are stacked to form the dielectric layer 120 of the capacitor, the capacitor may have desired characteristics such as high capacitance and low leakage current.

The above-described layer deposition apparatus and the layer deposition method may be used to manufacture a semiconductor device such as a logic device or a memory device. The semiconductor device may include logic devices, e.g., central processing units (CPUs), main processing units (MPUs), or application processors (APs), or the like, and volatile memory devices, e.g., dynamic random access memory (DRAM) devices, high bandwidth memory (HBM) devices, or non-volatile memory devices, e.g., flash memory devices, phase change random access memory (PRAM) devices, magnetic random access memory (MRAM) devices, resistive random access memory (ReRAM) devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A method of depositing a layer, the method comprising:
i) loading a substrate on a substrate stage within a chamber;
ii) alternately supplying a precursor gas and a reaction gas into the chamber to form at least one atomic layer;
iii) planarizing a surface of the at least one atomic layer by applying pressure on the surface of the at least one atomic layer to diffuse atoms located on the surface having a relatively high curvature; and
iv) alternately supplying the precursor gas and the reaction gas into the chamber to form at least one atomic layer on the planarized atomic layer.

2. The method of claim 1, wherein planarizing the surface of the at least one atomic layer includes applying vibration pressure to the surface of the at least one atomic layer.

3. The method of claim 1, wherein planarizing the surface of the at least one atomic layer includes applying radiation pressure to the surface of the at least one atomic layer.

4. The method of claim 1, wherein planarizing the surface of the at least one atomic layer includes generating a mechanical bombardment on the surface of the at least one atomic layer.

5. The method of claim 1, wherein the at least one atomic layer has a thickness of 0.2 Å to 0.8 Å.

6. The method of claim 1, further comprising:
v) performing the step iii) after the step iv); and
repeatedly performing the step iv) and the step v) until the atomic layer has a desired thickness.

7. The method of claim 6, wherein the desired thickness of the atomic layer is within a range of 30 Å to 80 Å.

8. The method of claim 1, wherein the precursor gas includes zirconium or hafnium.

9. The method of claim 1, further comprising:
supplying a boost gas into the chamber to increase pressure inside the chamber.

10. The method of claim 9, wherein the pressure of the chamber increased by the boost gas is at least 1 atm.

11. A method of depositing a layer, the method comprising:
i) alternately supplying a precursor gas and a reaction gas into a chamber to form at least one atomic layer;
ii) diffusing atoms located on a surface of the at least one atomic layer to planarize a surface of the at least one atomic layer; and
iii) repeatedly performing the step i) and the step ii) until the atomic layer has a desired thickness.

12. The method of claim 11, wherein planarizing the surface of the at least one atomic layer includes applying vibration pressure to the surface of the at least one atomic layer.

13. The method of claim 11, wherein planarizing the surface of the at least one atomic layer includes applying radiation pressure to the surface of the at least one atomic layer.

14. The method of claim 11, wherein planarizing the surface of the at least one atomic layer includes generating a mechanical bombardment on the surface of the at least one atomic layer.

15. The method of claim 11, wherein the at least one atomic layer has a thickness of 0.2 Å to 0.8 Å.

16. The method of claim 11, wherein the desired thickness of the atomic layer is within a range of 30 Å to 80 Å.

17. The method of claim 11, wherein the precursor gas includes zirconium or hafnium.

18. The method of claim 11, further comprising:
supplying a boost gas into the chamber to increase pressure inside the chamber, after the step i).

19. The method of claim 18, wherein the pressure of the chamber increased by the boost gas is at least 1 atm.

20. The method of claim 11, wherein the at least one atomic layer include zirconium oxide and hafnium oxide.

21. (canceled)
